(19) United States
(12) Patent Application Publication
(10) Pub. No.: US 2017/0194171 A1
(43) Pub. Date: Jul. 6, 2017

(54) Manufacture of Circuit Assembly with Unpackaged Semiconductor Devices

(71) Applicant: Rohinni, LLC, Coeurd'Alene, ID (US)

(72) Inventors: Cody Peterson, Hayden, ID (US); Andrew Huska, Liberty Lake, WA (US); Kasey Christie, Hayden, ID (US); Clinton Adams, Coeurd'Alene, ID (US); Orin Ozias, Austin, TX (US)

(21) Appl. No.: 15/316,505

(22) PCT Filed: Jun. 6, 2015
(86) PCT No.: PCT/US15/34596

§ 371 Date: Dec. 5, 2016

Related U.S. Application Data
(60) Provisional application No. 62/146,956, filed on Apr. 13, 2015.
(60) Provisional application No. 62/136,434, filed on Mar. 20, 2015.
(60) Provisional application No. 62/009,094, filed on Jun. 6, 2014.

(51) Int. Cl. H01L 21/50; H01L 23/31; H01L 21/683; H01L 25/03; H01L 23/00

(52) U.S. Cl. CPC H01L 21/50; H01L 25/03; H01L 24/24; H01L 21/6836; H01L 23/3121; H01L 2221/68354; H01L 2221/68327

(57) ABSTRACT

An apparatus includes a carrier-to-circuit transfer mechanism that is configured to obtain one or more unpackaged semiconductor devices on a carrier substratum and directly transfer the one or more unpackaged semiconductor devices from the carrier substratum to a circuit assembly. The apparatus further includes an in-situ packager that is configured to in-situ package the one or more transferred devices by interconnecting each semiconductor device of the one or more transferred devices to conductive links of the circuit assembly and applying a coating material to the one or more transferred devices.

### CROSS REFERENCE TO RELATED PATENT APPLICATIONS

This application is a national stage application of an international patent application PCT/US15/34596 filed Jun. 6, 2015, which claims priority to U.S. provisional application 62/146,956 filed Apr. 13, 2015, which claims priority to U.S. provisional application 62/136,434 filed Mar. 20, 2015, which claims priority to U.S. provisional application 62/009,094 filed Jun. 6, 2014, which applications are hereby incorporated by reference in their entireties.

### BACKGROUND

Semiconductor devices are electrical components that utilize semiconductor material (such as silicon, germanium, gallium arsenide, and the like). Semiconductor devices are typically manufactured as single discrete devices or as integrated circuits (ICs). Examples of single discrete devices include light-emitting diodes (LEDs), diodes, transistors, resistors, capacitors, fuses, and the like.

The fabrication of semiconductor devices typically involves an intricate manufacturing process with a myriad steps. The end-product of the fabrication is a packaged semiconductor device. A “packaged” modifier refers to the enclosure and protective features built into the final product as well as the interface that enables the device in the package to be incorporated into an ultimate circuit.

The conventional fabrication process for semiconductor devices starts with a semiconductor wafer. The wafer is diced into a multitude of unpackaged semiconductor devices. Herein, unpackaged semiconductor devices may be called semiconductor device dies. Indeed, the actions between the wafer handling and the packaging can be called “die preparation.” After such preparation, the conventional fabrication process packages each of the dies.

Typically, the packaging involves mounting a die into a plastic or ceramic package (e.g., mold or enclosure). The packaging also includes connecting the die contacts to pins/wires for interfacing/interconnecting with ultimate circuitry. The packaging of the semiconductor device is typically completed by sealing the die to protect it from the environment (e.g., dust, temperature, and/or moisture).

A product manufacturer includes the packaged semiconductor devices in the circuitry of their product. Because of their packaging, the devices are ready to be “plugged in” to the circuit assembly of the product that the manufacturing is making. Because of their packaging, the devices are protected from the elements that might degrade or destroy the device. In addition, because of their packaging, the devices are inherently larger (e.g., typically around than 10 times the thickness and 10 times the area, resulting in 100 times the volume) than the die found inside the package. Thus, the resulting circuit assembly cannot be any thinner than the packaging of the semiconductor devices.

### BRIEF DESCRIPTION OF THE DRAWINGS

FIG. 1 illustrates a conventional die-to-end-product meta-manufacture 100.

FIG. 2 illustrates an example of an implementation 200 of the novel die-to-end-product meta-manufacture technology, in accordance with the technology and techniques described herein.

FIGS. 4A and 4B illustrate examples of implementations of circuit production approach, in accordance with the technology and techniques described herein.

FIG. 5 illustrates an example of an implementation of direct carrier-to-circuit transfer technology, in accordance with the technology and techniques described herein.

FIGS. 6A-6D illustrate cross-sections of examples of implementations of in-situ packaging technology, in accordance with the technology and techniques described herein.

FIGS. 7 and 8 are flow diagrams illustrating example processes in accordance with the technology and techniques described herein.

The Detailed Description references the accompanying figures. In the figures, the left-most digit(s) of a reference number identifies the figure in which the reference number first appears. The same numbers are used throughout the drawings to reference like features and components.

### DETAILED DESCRIPTION

Disclosed herein are techniques and technologies for the efficient and effective manufacture electronic products (e.g., mobile devices, computers, etc.) that incorporate circuitry with semiconductor devices. The new approach conflates two disparate manufacturing processes into a single manufacturing process. Conventionally, a semiconductor device manufacturer produced, sold, and distributed packaged devices. A product manufacturer purchased the packaged devices and then incorporated such devices into their electronic products.

In contrast, with the new approach, a product manufacturer incorporates unpackaged semiconductor devices (i.e., dies) into the circuitry of their products. With the new approach, the product manufacturer can package the dies and their related circuitry in-place (which is called “in-situ packaging” herein).

### Typical Die-to-End-Product Meta-Manufacturing

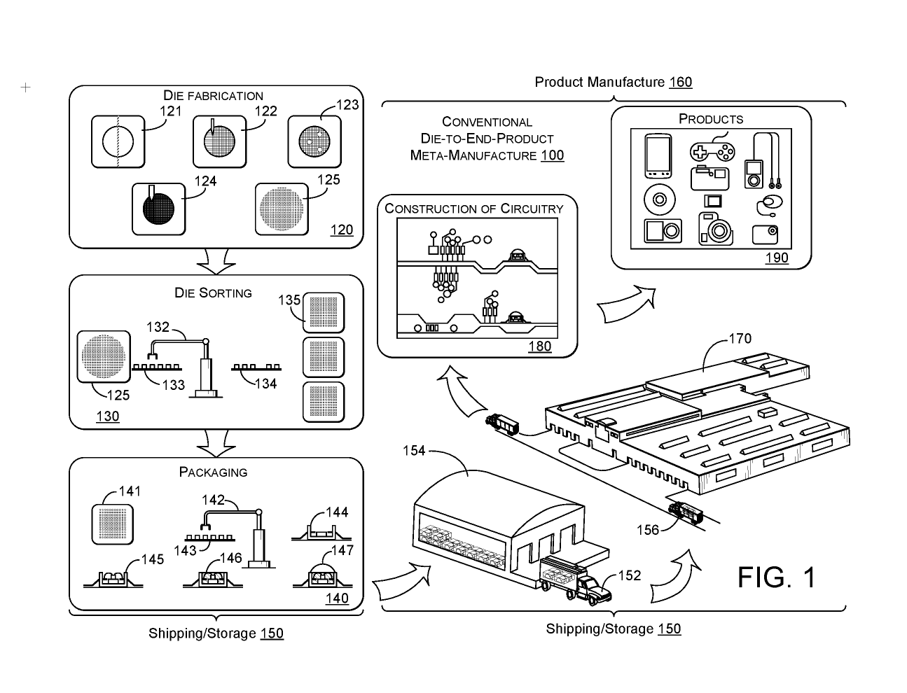

FIG. 1 illustrates a conventional die-to-end-product meta-manufacture 100. The meta-manufacture usually includes three parts: semiconductor-device-package manufacture 110, shipping/storage 150, and product manufacture 160.

The semiconductor-device-package manufacture 110 includes die fabrication 120, die sorting 130, and die packaging 140.

Before the die fabrication 120 starts, a wafer manufacturer supplies a semiconductor wafer. A typical wafer is sliced from ingots of silicon or other semiconductor material. Each wafer includes many (e.g., hundreds, thousands, or millions) semiconductor devices. Semiconductor devices are typically manufactured as single discrete devices or as integrated circuits (ICs). Examples of single-discrete devices include light-emitting diodes (LEDs), diodes, transistors, resistors, capacitors, fuses, and the like. For illustration purpose, the LED is a concrete example of a semiconductor device discussed herein. More particularly, the LED is the concrete example of a single-discrete semiconductor device discussed herein.

The die fabrication 120 includes wafer-mounting 121, wafer etching 122, die-testing 123, wafer-dicing 124, and wafer stretching 125. The die fabrication is sometimes called die preparation. Those of ordinary skill in the art view conventional die preparation as the step in the semiconductor device fabrication in which a wafer is prepared for packaging and/or testing.

During wafer mounting 121, the wafer is mounted on a stretchy low-tack adhesive tape that is itself attached to a ring. This tape is generally called “dicing tape” or more commonly “blue tape,” since it traditionally has a blue hue. Since the dicing tape holds or carries the wafer (and ultimately the dies) it is often generically called carrier tape or more simply as the carrier.

The dicing tape is often made from flexible and stretchy material (such as polyvinyl chloride (PVC)) and has an adhesive (e.g., acrylic or synthetic acrylic) bonded on one side. The dicing tape typically has a high tear strength, is flexible, and stretchy. Generally, one of the main purposes of the dicing tape is to ensure that the individual dies remain firmly in place during dicing 124 of the wafer into separate dies.

After the wafer is mounted, the wafer is etched 122 and diced 124. The wafer etching may also be called scoring. The wafer dicing may be called semiconductor-die cutting. Sometimes the combination of etching/dicing is called die singulation.

During the die singulation (e.g., etching 122 and dicing 124), the wafer is cut into shapes, which are normally rectangular. These rectangular pieces are each called a die. In between those functional parts of the circuits of the wafer, a thin non-functional spacing is foreseen where a saw (or the like) can safely cut the wafer without damaging the circuits of the semi-conductor devices in the wafer. Usually the dicing is performed with a water-cooled circular saw with diamond-tipped teeth.

During the testing 123, each semiconductor device is subjected to various testing. From this testing, various properties of each device is determined and tracked. That is, a database or map of the devices of the wafer is created that records the determined properties of each device. Herein, this may be called “device map,” “die database,” or the like. As depicted in FIG. 1, the testing 123 is shown as occurring between the etching 122 and the dicing 124. In other instances, the testing can occur at other points during the die fabrication 120.

Typically, the testing 123 involves testing the dies on the wafer with an electronics tester that presses tiny probes against the die. The testing often involves determining the electrical functionality of the circuitry of the die. For example, when an LED die is tested, its luminance properties are tracked. Such luminance properties may include brightness, color, and the like.

After the die singulation, the wafer is typically stretched 125. This is also called wafer expansion. The dicing tape on which the wafer is adhered is stretched out radially to increase the spacing between the now physically separated dies of the wafer. The typical reason for doing this is to prevent die edge damage during shipping or during the conventional pick-and-place operation.

In many instances, the die sorting 130 occurs next after the die fabrication. This may be called die binning. The purpose of the die sorting is to collect like dies together in “bins.” The dies are sorted based upon their properties as determined during the testing 123.

The die sorting 130 starts with the stretched wafer 125, which was the result of the die fabrication 120. A pick-and-place machine 132 picks up individual dies from the stretch wafer. As depicted, stretched wafer 133 is a side elevation view of the same stretched wafer 125. Stretched wafer 134 shows the same wafer 133 after one die has been removed. The pick-and-place machine 132 places the dies into one or many “bins” 135 (or binned carriers). The bins are often a matrix of dies on dicing tape. Each bin contains like or similar dies based upon one or more properties.

The pick-and-place machine 132 is the kind of machine commonly used by fabricators of semiconductor devices (e.g., LEDs) to transfer their devices from one location to another. In particular, such machines are used to pick a single-discrete device (e.g., LED) from one carrier tape to another. As shown, with the die sorting 130, the pick-and-place machine 132 picks a die off the original carrier 133/134 and places onto one of multiple binned carriers 135.

The packaging 140 stage starts with one of the binned carriers (shown as carrier 141) of like dies. A pick-and-place machine 142 is shown picking a die from a side elevation view of the carrier 143 and placing it into a package mold 144. This is often called mounting. The packaging mold 144 is often made of plastic or ceramic. At 145, wires are added to connect the electrical contacts of the die to the packaging's external contacts. At 146, the mold is filled with an environmentally protecting sealant. Often, the die is capped as is shown at 147. If the die is an LED, then often this cap is a lens to focus and direct the light.

Wikipedia.com describes a semiconductor package in this manner:
A semiconductor package may have as few as two leads or contacts for devices such as diodes, or in the case of advanced microprocessors, a package may have hundreds of connections. Very small packages may be supported only by their wire leads. ///
In addition to providing connections to the semiconductor and handling waste heat, the semiconductor package must protect the “chip” from the environment, particularly the ingress of moisture. Stray particles or corrosion products inside the package may degrade performance of the device or cause failure. A hermetic package allows essentially no gas exchange with the surroundings; such construction requires glass, ceramic or metal enclosures.

As represented by packaged device 147, the packaged semiconductor device (e.g., an LED) is the sellable product that is the result of the semiconductor-device-package manufacture 110.

Often, the device-packager collectively packages the packaged devices for ease of distribution to a product manufacturer and ease of placement into a circuit by that same manufacturer. For example, after each device is packaged, the packager collects multiple packaged devices together and places them into a distribution packaging, which is often called a “reel.” For example, each packaged device is placed onto a strip of tacky tape and/or into a bubble/blister containment strip.

The shipping/storage 150 part includes a warehouse 152 and shipping 154, 156 to/from that warehouse. Typically, the packaged devices are purchased by commercial enterprises, especially device/product manufactures. Until such purchase, the packaged devices are stored. The shipping/storage 150 part represents the typical scenario where the manufacturer of the packaged devices ships 152 their goods to a warehouse 154 for storage while awaiting orders or as part of a distribution system. From the warehouse 154, the purchased packaged devices are delivered 156 to a product manufacturer 170, for example. Sometimes the shipment/delivery (152/156) may be across a nation or an ocean. That adds time and cost to the overall die-to-end-product meta-manufacture 100.

The product manufacture 160 part includes the product manufacturer 170 itself, construction 180 of the circuitry that will go into an electronic product, and manufactured products 190.

The product manufacturer 170 is a company that creates and/or sells an electronic device or product or some portion thereof. For example, the product manufacturer 170 may be an original equipment manufacturer (OEM). An OEM is a company that makes a part or subsystem that is used in another company's end-product. Regardless, the final product that is being built has some electronic circuitry included therein.

At 180, that electronic circuitry is constructed. Such construction typically includes, for example, placing electronic components (e.g., transistors, diodes, ICs, batteries, resistors, capacitors, and the like) on a printed circuit board (PCB) and electronically linking such components using wires or other conduct tracks. Indeed, PCBs typically have conductive layers and non-conductive layers. The PCB offers mechanical support and insulation for the electronic components and their conductive links.

The packaged devices (such as device 147) are an example of the type of electronic component that is used in the construction of electronic circuitry at 180. Since the packaged device is already protected from environmental elements, the constructed circuitry does not necessarily needs environmental protection.

One or more of the completed circuitry is assembled together with other mechanical and functional parts to form an intermediate sub-system or the end-product itself. Regardless, at some point in the overall product manufacturing process, the end-product is finally assembled and is ready to be distributed to customers and/or retail outlets. Herein, the end-product may simply be called “product.” The end-product may be most any device with electronic circuitry therein. Examples of such end-products include mobile phones, game controllers, digital music players, digital cameras, toys, video game consoles, computer input devices, medical devices, televisions, computers, appliances, automobiles, ebook readers, and the like.

### Example of Die-to-End-Product Meta-Manufacturing Technology

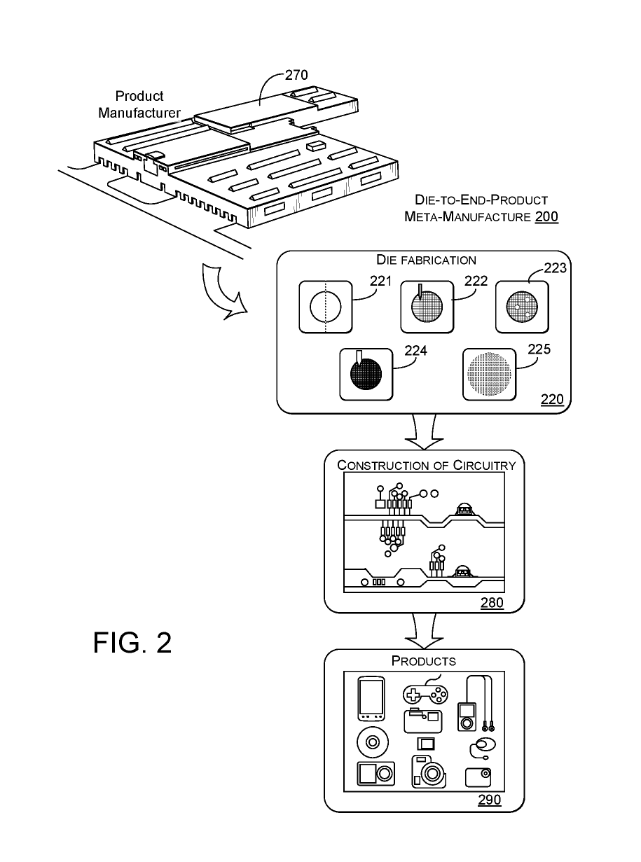

FIG. 2 illustrates an example of an implementation 200 of the novel die-to-end-product meta-manufacture technology, as described herein. Henceforth, this example implementation is called “meta-manufacture technology 200.” To demonstrate some of the differences between the conventional process and the new approach described herein, the description of this implementation 200 will be contrasted with the conventional die-to-end-product meta-manufacture process 100 shown in FIG. 1 and described above. The demonstrated differences will highlight some of the efficiencies and effectiveness of the new approach described herein.

As depicted, the meta-manufacture 200 includes a die fabrication 220, construction 280 of the circuit assembly that will go into an electronic product, and manufactured products 290. The actions/parts of the meta-manufacture 200 are performed by product manufacturer 270 and potentially at single plant/factory/location.

With the technology and techniques described herein, many of the steps and complications of the conventional process 100 are unnecessary and thus eliminated. In short, unpackaged semiconductor devices are directly transferred from its carrier to a circuit assembly, which will later be placed into the end-product. During the circuit assembly construction, the unpackaged semiconductor devices are effectively packaged in-situ (i.e., in place).

With the meta-manufacture technology 200, die fabrication 220 and product manufacturing can occur at the same location and, indeed, as part of the same manufacturing process. Consequently, the meta-manufacture technology 200 eliminates the shipping/storage/distribution part of the conventional process 100.

The die fabrication 220 of the meta-manufacture 200 occurs in a manner similar and consistent with the die fabrication 120 of the conventional die-to-end-product meta-manufacture process 100 shown in FIG. 1 and described above. Consequently, existing equipment and supplies for die fabrication may be employed for the die fabrication 220 of the meta-manufacture 200.

The die fabrication 220 includes wafer-mounting 221, wafer etching 222, die-testing 223, wafer-dicing 224, and wafer stretching 225. During wafer mounting 221, the wafer is mounted on a carrier, such as dicing tape.

After the wafer is mounted, the wafer is singulated by etching 222 and dicing 224. During the die singulation, the wafer is cut into dies. During the testing 223, the semiconductor devices are tested and a “device map” or “die database” is created. After the die singulation, the wafer is typically stretched 225.

At 280, the circuit assembly is constructed. The details of implementations of how this is accomplished is described henceforth. In part, the circuit assembly construction 280 includes a direct transfer from its carrier to the circuit assembly, which will later be placed into the end-product. During the circuit assembly construction 280, the unpackaged semiconductor devices are effectively packaged in-situ (i.e., in place).

One or more of the completed circuit assembly is assembled together with other mechanical and functional parts to form an intermediate sub-system or the end-product itself. Regardless, at some point in the overall product manufacturing process, the end-product is finally assembled and is ready to be distributed to customers and/or retail outlets. The end-product may be most any device with electronic circuitry therein. Examples of such end-products includes mobile phones, game controllers, digital music players, digital cameras, toys, video game consoles, computer input devices, medical devices, televisions, computers, appliances, automobiles, ebook readers, and the like.

### Example Circuitry Construction Technology

FIG. 3 illustrates an example of an implementation 300 of the circuitry construction technology described herein. This implementation is called “circuitry construction technology 300” herein. This technology illustrates the main actions that occur as part of the construction of circuit assembly 280 as shown in FIG. 2 and discussed above.

The circuitry construction technology 300 includes direct transfer 310 of die to circuit assembly, circuitry production 320, and in-situ packaging 330.

As depicted in a simplified form, the direct transfer 310 includes a stretched wafer (shown in both a top plan view at 312 and a side elevation view at 316), a die-to-circuit transfer mechanism 314, and a circuit assembly 318.

The stretched wafer 312/316 has many dies adhered to one side of a carrier substratum (e.g., an adhesive dicing tape). As shown, the die-to-circuit transfer mechanism 314 (or simply transfer mechanism) includes a reciprocating pin that moves up and down. The circuit assembly 318 includes a circuit substrate and, in some implementations, some portion of the circuitry already on or in the circuit substrate (or simply “substrate” herein). As used herein, a circuit assembly includes a circuit substrate and existing conductive links and/or it is prepared to receive/accept conductive links for the ultimate purpose of completing a functioning circuit with the resulting circuitry of the circuit assembly.

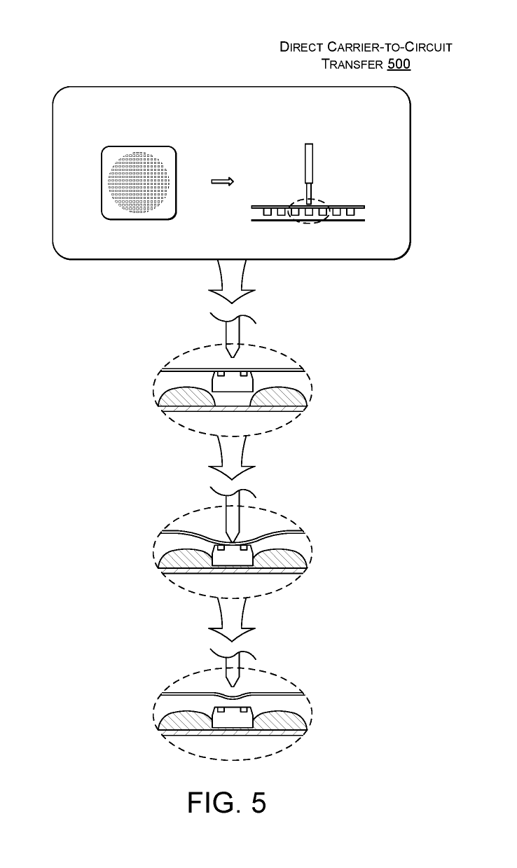

The parts are arranged in the manner shown in block 310. From top to bottom, they are arranged with the transfer mechanism 314 on top, the circuit assembly 318 on bottom, and the stretched wafer 316 interposed therebetween. Furthermore, they are arranged so that receiving side of the circuit assembly 318 and the die side of the carrier substratum face each other. The transfer mechanism is arranged so that it is on the side opposite of the carrier substratum of the dies. The direct transfer is accomplished, for example, by an up-and-down movement or a to-and-fro type movement. This is discussed more hereafter in the context of FIG. 5.

The circuitry itself is produced at 320. The circuitry is typically constructed from or is already part of the circuit assembly 318. The circuit assembly 318 includes the substrate. Typically, as used herein, the substrate is a planar material that is sufficiently strong to support circuitry thereon or therein. Examples of such material include (but is not limited to) polyethylene terephthalate (PET), polyester, polyvinyl chloride (PVC), a polyamide film (such as Kapton™), printed circuit board (PCB), or the like. Often the substrate is thin. The substrate may be flexible or rigid. The substrate is not dicing tape or other similar stretchy material.

Once on the substrate of the circuit assembly 318, the dies are firmly affixed to the substrate. This may be accomplished in numerous manners. Examples of which include:
The curing of the circuit causing the pads of the LED to bond to the circuit.
The substrate may be covered in an adhesive (that is presumably tackier than the adhesive used on the carrier substratum).
Small amounts of adhesive are dropped on the circuit assembly 318 in the precise locations where the die is expected/planned to be transferred thereto.
An affixing coating is sprayed over the circuit assembly 318 and the transferred dies to hold the dies in place.
The direct transfer mechanism 314 may deposit an adhesive onto and over the transferred die in a manner where the pin of mechanism acts as a hypodermic needle.

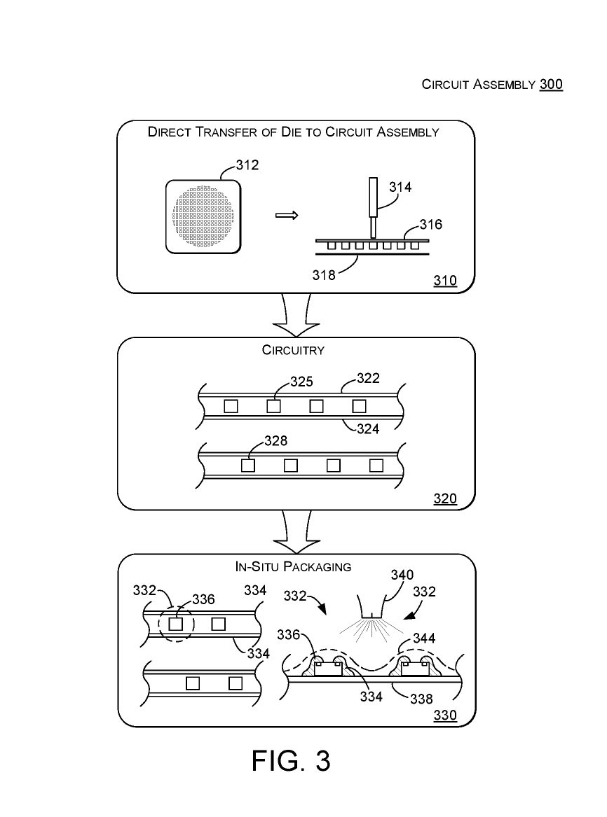

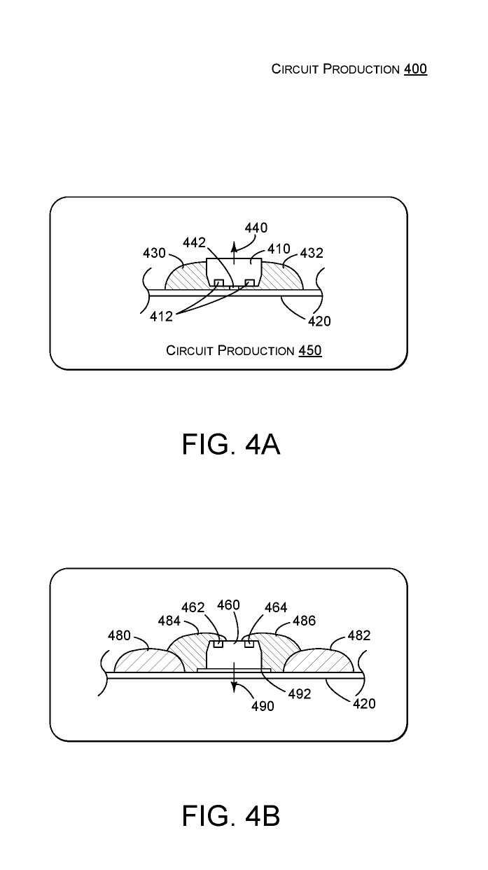

The circuitry is produced on or in the substrate of the circuit assembly 318 either before or after the direct transfer illustrated in block 310. For discussion purposes, the instance of the circuitry being produced on the substrate after the direct transfer is discussed. Other alternatives and options will be discussed hereafter in the context of FIGS. 4A and 4B.

As shown at 320, conductive links (e.g., conductive traces 322, 324) are deposited onto the substrate of the circuit assembly 318 before the direct transfer of the dies, as illustrated by block 310. Then, the dies (e.g., dies 326, 328) are placed on the substrate of the circuit assembly 318.

As shown, dies (such as dies 326 and 328) are placed between or otherwise near traces. In some situations, the placement of the dies alone may be sufficient to make electrical contact with traces.

The in-situ packaging 330 occurs after the direct carrier-to-circuit die transfer 310 and the circuitry production 320. The term “in-situ” includes the concept of “in place” or “in its existing place or position.” More particularly, as used herein, in-situ packaging includes a form of “packaging” a die once it is in its place in or on the circuit assembly. This is contrasted with the conventional packaging where each individual die is affixed to a mold designed specifically to receive that die. The die is handled in a manner so that the packaged device offers a standardized way to connect to a circuit, protects the device, and possibly alters some of the properties of the device (e.g., color adjustment of a LED).

The left side of the in-situ packaging 330 block shows a top plan view of the transferred device 331 of the circuit assembly. This view also shows a highlighted dashed line circle 332. The right side of the in-situ packaging 330 block shows a cross-section view of the highlighted dashed line circle 332

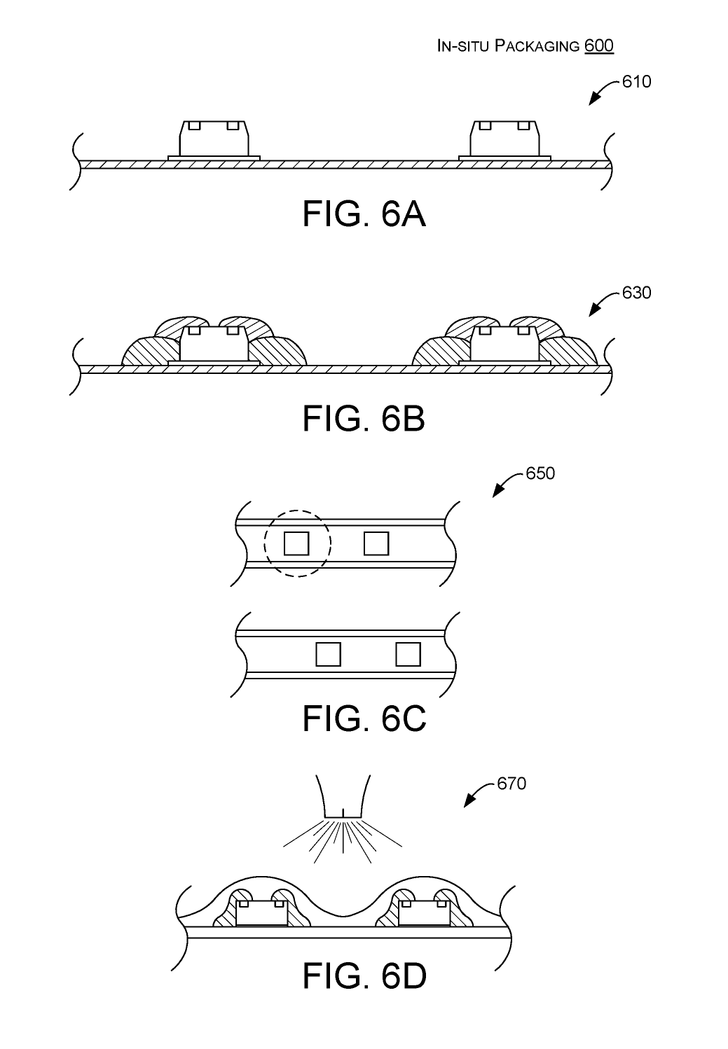

Already transferred device 331 is shown in the highlighted dashed line circle 332 of the in-situ packaging 330. As depicted, device 331 has at least one conductive trace 334. Conductive interconnections (as is shown at 336) are added to connect electrical contacts 337 of the device 331 to the conductive trace 334. This example and other example implementations are discussed hereinafter with regard to FIG. 6 and its related discussion.

The right side of in block 330 shows a cross-section view of the circuitry on a substrate 338 of the circuit assembly. This shows the device 332, its conductive trace 334, and the interconnection 336 therebetween.

The block 330 also shows a coating nozzle 340, which is shown spraying a liquid coating material 342 onto and over the circuitry of the circuit assembly. In particular, the coating covers the device 331, its conductive trace 334, and their interconnection 336. The dried and/or cured coating is shown at 344.

This coating may be designed for many purposes, such as protecting the devices from environmental concerns (e.g., heat, humidity, cold, moisture, dust, etc.) Further discussion is provided later in the context of FIG. 6 and its related description.

FIGS. 4A and 4B illustrate examples of implementations (400 and 450 respectively) of circuit production approach for the circuitry construction technology described herein.

FIG. 4A shows the example implementation 400 that includes an unpackaged light-emitting diode (LED) 410, a substrate 420, and a pair of conductive traces 430, 432. A dielectric 442 separates the traces 430 and 432. The LED die 410 has two electrical contacts (412 and 414) and arrow 440 indicate the primary direction of travel for the light emanating from the LED die 410.

As shown in example 400, the LED die 410 is placed “top-down” or “face-down” relative to the substrate 420. While there is not an actual “top” or “face” on the LED die 410, the side of the LED die that has both electrical contacts (412 and 414) thereon is called the “top” or “face” herein. The LED die 410 is placed top-down and in a position so that each contact makes an operative electrical connection to one of the traces. For example, contact 412 makes an operative electrical connection with the conductive trace 430.

To accomplish this, the conductive traces 430, 432 are deposited onto the substrate 420 before the LED die 410. In addition, the LED die 410 is placed onto the substrate 420 while the traces are still liquid or moldable. Thus, the LED die 410 is laid down on/over the traces 430, 432 before the curing or drying of the traces.

As shown, the traces are laid down in the physically parallel fashion and with sufficiently small space therebetween to enable each trace to make an electrical connection to one of the contacts of the die. However, there should be sufficient space therebetween the traces to avoid having the traces bleeding into each other (or being close enough to touch/arc) and causing a short when the power is supplied to the circuitry.

The circled area 442 represents the dielectric space between the traces. This dielectric space may include air or some other dielectric material that is laid down between the conductive traces. In at least one implementation, the distance between the contacts is 50 microns. Thus, in that implementation, the dielectric space is 50 microns wide or less. The conductive traces and/or the other dielectric material may have adhesive properties to affix (i.e., mechanically attach) the LED die 410 to the substrate 420.

In this scenario, the traces, the dielectric material, and/or the substrate may be non-translucent. Indeed, they may be reflective. Consequently, the general direction of the majority of the emitted and reflected light is represented by arrow 440. In alternative instances, the traces, dielectric material, and/or substrate may be translucent or even fully transparent. In those instances, the light may also be emitted and/or reflected in other directions other than that represented by 440.

FIG. 4B shows the example implementation 450 that includes an unpackaged light-emitting diode (LED) 460, a substrate 470, and a pair of conductive traces 480, 482. The LED die 460 is affixed to the substrate 470 with an adhesive 492 (e.g., a UV curable adhesive).

Interconnecting conductive material 484, 486 connect to electrical contacts (462 and 464), respectively, of the LED die 460. Arrow 490 indicates the primary direction of travel for the light emanating from the LED die 460.

As shown in example 450, the LED die 460 is placed “top-up” or “face-up” relative to the substrate 470. While there is not an actual “top” or “face” on the LED die 460, the side of the LED die that has both electrical contacts (462 and 464) thereon is called the “top” or “face” herein. The LED die 460 is placed top-up and in a position between conductive traces 480 and 482. After placement, the interconnecting conductive material is added to operatively electrical connect each contact to a trace. For example, interconnecting conductive material 484 forms an operative connection between traces 480 and contact 462.

To accomplish this, the conductive traces 480, 482 are deposited onto the substrate 470 before the LED die 460 is placed on the substrate. Between the traces (480, 482), the adhesive 492 is placed exactly where the LED die is desired. Then, the LED die 460 is placed onto the substrate 470 onto the adhesive 492. The adhesive 492 dries or is cured to firmly affix the LED die 460 on the substrate 470. In some implementations, the adhesive 492 is 25 microns thick or less. Next, the interconnecting material (e.g., 484 and 486) is deposited in a manner operatively connect the contacts of the LED die 460 to the conductive traces. The interconnecting material may be laid down by, for example, a precision fluid dispensing device (such as an AdvanJet™ HV-2000). Then, the interconnecting material is cured or dried.

In this scenario, the traces, the adhesive, and/or the substrate is translucent. Indeed, they may be transparent. Consequently, the general direction of the majority of the emitted and reflected light is represented by arrow 490. In alternative instances, one or more of the traces, the adhesive, or the substrate may be opaque (i.e., non-translucent) or perhaps reflective. In those instances, the light may also be emitted and/or reflected in other directions other than that represented by 490.

### Example Direct Carrier-to-Circuit Transfer Technology

FIG. 5 illustrates an example of an implementation 500 of direct carrier-to-circuit transfer technology of the circuitry construction technology described herein.

As depicted in a simplified form, the direct transfer 500 includes a stretched wafer 510, which is shown in a top plan view on the left and in a cross-section on the right. The stretched wafer 510 includes stretched carrier substratum 512 (e.g., adhesive dicing tape) with many unpackaged semiconductor devices (such as die 550) adhered to one side. As shown in the cross-section, the direct transfer 500 also includes a die-to-circuit transfer mechanism 530 and a circuit substrate 520.

From top to bottom, the transfer mechanism 530 on top, the circuit substrate 520 on bottom, and the stretched wafer 510 interposed therebetween. This top-to-bottom arrangement is shown to illustrate the alignment of the components and parts. In other implementations, the components may be aligned at angles and directions that differ from top-to-bottom. For example, they could be side-to-side or at an angle.

The components are arranged so that receiving side of the circuit substrate 520 and the die side of the carrier substratum 512 face each other. The transfer mechanism 530 is arranged so that it is on the side of the carrier substratum 512 that is opposite of the dies. The direct transfer is accomplished, for example, by an up-and-down movement or a to-and-fro type movement.

A pin of the direct transfer mechanism 530 is designed to press down on each die (such as die 550) to put the die into physical contact with the circuit substrate and at a particular desired location. The carrier substratum stretches during the pinning action. Once the pin is retracted, the elastomeric (i.e., stretchy) tape releases the pinned die and elastomerically returns to its natural upstretched state.

As shown in FIG. 5, a dashed circle 540 indicates a region of interest that is discussed herein in the context of a series of close-ups of the region. The sequential close-ups of the region of interested are labeled A, B, and C and may be called 540A, 540B, and 540C respectively.

At 540A, the die 550 is shown still adhered to the carrier substratum 512 and suspended over the circuit substrate 520. At this point, the direct transfer mechanism 532 has not moved. As shown, the face-up implementation is illustrated. This is demonstrated by electrical contacts 552 being face-up. The circuit substrate 520 has two parallel conductive links 522, 524 with an adhesive 526 therebetween. The die 550 is suspended above the adhesive 526 and between the conductive links 522, 524.

The distance between the carrier substratum 512 and the circuit substrate 520 is 5 millimeters or less. In some implementations, the distance is less than two millimeters. In still other implementations, the distance is less than one millimeter.

At 540B, the pin of the direct transfer mechanism 530 is shown having moved vertically downward, as indicated by arrow 532. In so doing, the pin pushes the die 550 downward towards the circuit substrate 520 and stretches the carrier substratum 512. The region 560 indicated by a dashed circle is the region where the pin makes contact with the carrier substratum 512 at approximately the center of the die 550. As shown in region 560, the downward motion of the pin stretches the carrier substratum 512 and the substratum releases from the die 550 along its edges.

The downward motion of the pin impinges the die 550 onto the circuit substrate 520. With the alignment of the pin, die 550 and other material (such as adhesive 526 and conductive links 522, 544), the downward motion of the pin presses the die into the adhesive and potentially against the conductive links.

At 540C, the pin of the direct transfer mechanism 530 is shown retracting vertically upward, as indicated by arrow 534. In so doing, all force against the die or the carrier substratum 512 are released. In the trampoline like fashion, the substratum returns to nearly its original position and shape. This is shown in region 562. The die 550 is left adhered to the substrate 520. Later, a curing (or drying) of the adhesive 526 and/or links 522, 524 will permanently affix the die to the substrate 520.

The stretched wafer 510 may be a binned or un-binned collection of devices. Since a map of the dies is known, the direct transfer 500 may select particular dies on the stretched wafer 510 based upon the known properties of the selected die matching (or being a near fit) to the desired properties for a device that is to be placed at the desired location.

With regard to the direct transfer mechanism, one or more implementations involve a single-axis movement. A part (e.g., a pin) moves in one direction to impinge the carrier-adhered die to a circuit substrate. Then the same part retracts (in exactly the opposite direction) to leave the die on the circuit substrate and released from the carrier substratum. Thus, the movement is along a single axis. The single-axis movement is akin to that movement of a needle in a sewing machine. The carrier substratum may be translucent when stretched. This aids in the alignment of the to-be-transferred die onto the desired/target location on the substrate for the transfer.

Some implementations use a thrust pin. In one implementation, the thrust pin does not pierce the carrier substratum but it just domes the substratum, which releases when the pin is retracted. The die stays in place because of a greater adhesion on the circuit substrate. The adhesion that tacks the die to the substrate may be a chemical and/or electrostatic. In other implementations, the thrust pin actually pierces the carrier substratum and mechanically pushes the die off the carrier substratum and onto the substrate.

### Example In-Situ Packaging Technology

FIGS. 6A-6D illustrate cross-sections of examples of implementations 610, 630, and 650 of in-situ packaging technology 600 of the circuitry construction technology described herein.

Conventional packaging includes mounting a die into a plastic or ceramic package (e.g., mold or enclosure). The conventional packaging also includes connecting the die contacts to pins/wires for interfacing/interconnecting with ultimate circuitry. The conventional packaging of the semiconductor device is typically completed by sealing the die to protect it from the environment (e.g., dust, temperature, and/or moisture).

As depicted, the in-situ packaging 600 occurs after the direct carrier-to-circuit die transfer and the circuitry production. The term “in-situ” includes the concept of “in place” or “in its existing place or position.” More particularly, as used herein, in-situ packaging includes a form of “packaging” a die once it is in its place in or on the circuit (or at least the surface that will eventually become a circuit). This is contrasted with the conventional packaging where each individual die is affixed to a mold designed specifically to receive that die. The die is handled in a manner so that the packaged device offers a standardized way to connect to a circuit, protects the device, and possibly alters some of the properties of the device (e.g., color adjustment of a LED).

FIG. 6A shows the example implementation 610, which depicts the in-situ packaging approach that affixes the dies. This implementation 610 is analogous to the conventional packaging approach of mounting a die into a mold or enclosure. As depicted, two already transferred devices 612, 614 are affixed in a face-up orientation to a circuit substrate 620 via adhesive 622, 624 (e.g., curable adhesive). The face-up orientation is demonstrated by the positioning of contacts 616 relative to the substrate 620.

FIG. 6B shows the example implementation 630, which depicts an in-situ packaging approach, which connects the contacts 616 to the circuitry. This implementation 620 is analogous to the conventional packaging approach of connecting the die contacts to pins/wires for interfacing/interconnecting with ultimate circuitry. As depicted, die 612 has a pair of conductive links 632, 634. Conductive interconnections (as is shown at 642 and 644) are added to complete the electrical connection between the electrical contacts 616 of the die 612 to the conductive links 632, 634.

FIGS. 6C and 6D show the example implementation 650, which depicts the in-situ packaging approach that affixes the dies. This implementation 610 is analogous to the conventional packaging approach of mounting a die into a mold or enclosure.

FIG. 6C shows a top plan view of the transferred device 652 of the circuit assembly. This view also shows a highlighted dashed line circle 660. FIG. 6D shows a cross-section view of the highlighted dashed line circle 660

Already transferred device 652 is shown in the highlighted dashed line circle 660 of the implementation 650. As depicted, device 652 has as least one conductive trace 654. Conductive interconnections (as is shown at 656) are added to connect electrical contacts (674 as shown in FIG. 6D) of the device 652 to the conductive trace 654.

FIG. 6D shows a cross-section view of the circuitry on a substrate 672 of the circuit assembly. This shows the device 652, its conductive trace 654, and the interconnection 656 connecting the electrical contacts 674 of the device to the trace 654. The device 652 is affixed to the substrate 672 via a non-conductive adhesive 676.

FIG. 6D also shows a coating nozzle 680 that applies (e.g., sprays) a liquid coating material 682 onto and over the circuitry of the circuit assembly. In particular, the coating covers the device 652, its conductive trace 654, and their interconnection 656. The dried and/or cured coating is shown at 684.

This coating may be designed for many purposes, such as protecting the devices from environmental concerns (e.g., heat, humidity, cold, moisture, dust, etc.). It may also be designed to adjust the properties (e.g., color) of the coated devices.

### Exemplary Process

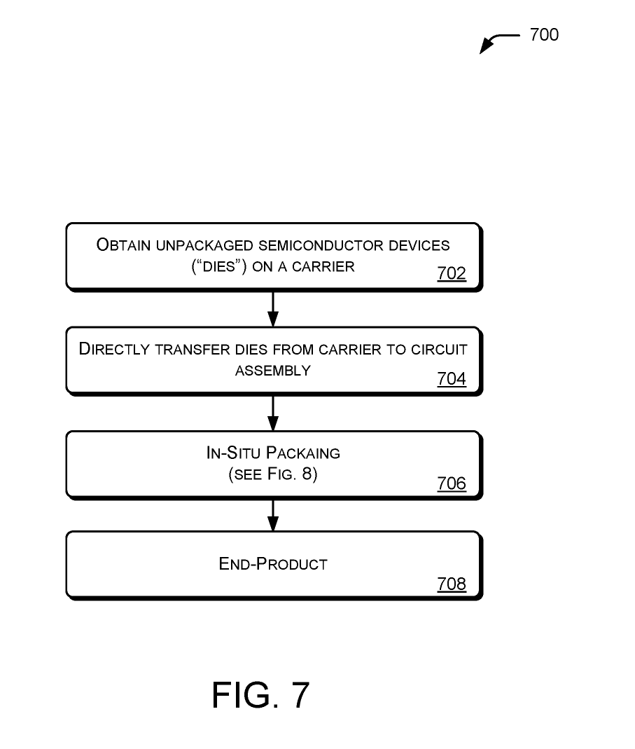

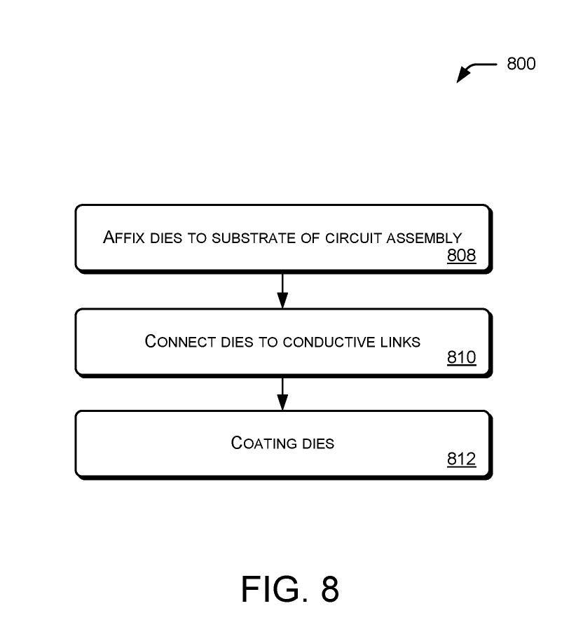

FIGS. 7 and 8 are flow diagrams illustrating example processes 700 and 800 that implement the techniques described herein. One or more system or apparatus may perform the example processes 700, 800. Examples of components, systems, or apparatuses that may perform all or some of the example processes include die fabricator, circuitry producer, carrier-to-circuit transfer mechanism, direct transfer mechanism, and in-situ packager.

At 702, the technology obtains one or more unpackaged semiconductor devices (“dies”) on a carrier substratum. The unpackaged semiconductor devices may be single discrete devices or integrated circuits (ICs). In some implementations, the unpackaged semiconductor devices are light-emitting diodes (LEDs). The carrier substratum is typically a planar material that is flexible and elastomeric. The carrier substratum has an adhesive bonded onto one side.

At 704, the technology directly transfers the one or more unpackaged semiconductor devices from the carrier substratum (or more simply “carrier” herein) to a circuit assembly. In some implementations, the carrier substratum is interposed between a direct transfer mechanism and the circuit assembly. In this way, the direct transfer mechanism can impinge the device to the substrate when it pushes the die downward.

In some implementations, the transference includes a reciprocating single-axis motion for the direct transference of each unpackaged semiconductor device from the carrier substratum to the circuit assembly. In some implementations, the transference includes placing the unpackaged semiconductor devices onto the circuit assembly in a face-up fashion.

The circuit substrate of the circuit assembly is typically planar and is configured to support the transferred dies thereon. In many implementations, the substrate is no thicker than 0.2 millimeters. In some implementations, there is also a disposing of conductive links on the circuit substrate of the circuit assembly. Moreover, this may be done before the direct transference.

At 706, the technology performs in-situ packaging the one or more transferred devices and/or their associated circuitry. Typically, this includes one or more of the following: affixing the transfer devices to the substrate, interconnecting the devices to circuitry, or coating or sealing the devices and/or their circuitry. This is discussed more with regard to FIG. 8 and example process 800.

At 708, the technology manufactures the end-product. More particularly, the end-product is an electronic product (e.g., mobile device, computer, etc.) that incorporates the constructed circuit assembly into operable circuitry of the electronic product. That constructed assembly may include the in-situ packaged circuitry and devices.

FIG. 8 shows the example process 800, which elaborates on the in-situ packaging of block 706.

At 802, the technology (e.g., in-situ packager) affixes the one or more transferred devices to the circuit substrate of the circuit assembly. In some implementations, this is accomplished using a curable adhesive. Depending upon the implementation, the adhesive may be transparent, translucent, or opaque. Depending upon the implementation, the adhesive may be conductive or non-conductive. In some implementations, the regions of adhesive are applied to the substrate in the specific places where a transferred die is desired. The size of the adhesive region may be half the size of the die to three times the size of the die. Once the die is placed onto the adhesive, the adhesive is cured to firmly affix the die to the substrate and avoid undesired adhesion by other material.

At 804, the technology interconnects each semiconductor device of the one or more transferred devices to conductive links of the circuit assembly. In some implementations, this may be accomplished by applying a continuous conductive material between a conductive link to an electrical contact of a transferred device.

At 806, the technology applies (e.g., “coats”) the one or more transferred devices with a coating material. The application may include a transfer of uncured liquid or gel coating material onto and over the circuit assembly (or just the one or more transferred devices) via actions selected from a group consisting of spraying, painting, printing, brushing, depositing, dispensing, powder-coating, coating, sealing, covering, glazing, laminating, enameling, incrusting, plastering, varnishing, dipping, immersing, slathering, bathing, dousing, drenching, dunking, and plunging.

The coating material may be a protective coating that protects the circuit assembly from environmental factors. In addition or in the alternative, the coating material may be a property-altering coating that adjusts the properties of the transferred device.

### Additional and Alternative Implementation Notes

As used herein, the modifier “direct” (or its like) as it is applied to a transfer in the context of a carrier-to-circuit transfer indicates that there is no intermediate step, placement, or locus of the die. Instead, it moves immediately from its carrier to the circuit assembly (which is where the circuit is or will be). There is no intermediate holding area or other carrier substratum where the die is stored before ultimately being placed into a circuit.

As used herein, semiconductor device refers to both single discrete devices or as integrated circuits (ICs). As used herein, a reference to a single-discrete semiconductor device (“SD semiconductor device) expressly excludes ICs, but includes devices such as light-emitting diodes (LEDs), diodes, transistors, resistors, capacitors, fuses, and the like.

The dies described herein may be LEDs. More particularly, the dies discussed herein may be miniLEDs. A miniLED is 10-400 microns in diameter. Some implementations described herein use miniLEDs with a diameter of 50-300 microns. Still other implementations use miniLEDs having a diameter of 90-270 microns. Still other implementations use miniLEDs having a diameter of 100-250 microns. Examples of real-word miniLEDs include CREE™ TR1823 (230×180×50 microns) and CREE™ TR2227 (220×270×50 microns). The contact pads of these CREE™ miniLEDs are roughly 60 microns apart diameter.

As used herein, semiconductor device refers to both single discrete devices or as integrated circuits (ICs). As used herein, a reference to a single-discrete semiconductor device (“SD semiconductor device) expressly excludes ICs, but includes devices such as light-emitting diodes (LEDs), diodes, transistors, resistors, capacitors, fuses, and the like. Unless the context indicates otherwise, the term “semiconductor device die” or simply “die” refers to an unpackaged semiconductor device.

The carrier substratum is planar material. It is often made from flexible and elastomeric (e.g., stretchy) material (such as polyvinyl chloride (PVC)) and has an adhesive (e.g., acrylic or synthetic acrylic) bonded on one side. The carrier substratum typically has a high tear strength, is flexible, and elastomeric. Generally, one of the main purposes of the carrier substratum is to ensure that the individual dies remain firmly in place during die singulation.

The circuit assembly includes a planar substrate that is configured to support transferred dies thereon. Unless the context indicates otherwise, the substrate, as used herein, is a planar material that is sufficiently strong to support circuitry thereon or therein. Examples of such material include (but are not limited to) polyethylene terephthalate (PET), polyester, polyvinyl chloride (PVC), a polyamide film (such as Kapton™), printed circuit board (PCB), or the like. Often the substrate is thin. A thin substrate is 0.1 to 0.15 mm thick or perhaps thinner. In some implementations, the thin substrate has a thickness of 0.07 to 0.2 mm. The substrate may be flexible or rigid. The substrate is not dicing tape or other similar elastomeric material.

The traces and/or interconnection material may be laid down on a substrate and/or over a die using one or more various approaches of precision fluid dispensing (PFD). Example of such PFD approaches include screen-printing, needle dispensing, drop/inkjet printing, and aerosol jet printing. Typically, the screen printing can produce traces/lines that are as narrow as 100 microns wide and 5 microns thick, the needle dispensing can produce traces/lines that are as narrow at 100 microns wide and 50 microns thick, the drop/inkjet printing can produce traces/lines that are as narrow as 150 microns wide and 75 microns thick, and the aerosol jet printing can produce traces/lines that are as narrow at 10-20 microns wide and as thick (in the z-dimension) as only a few microns (e.g., 3-10).

An AdvanJet™ HV-2000 is an example of dropjet printer that may be used in implementations described herein. Optomec™ is an example of a suitable aerosol jet technology that may be used in implementations described herein.

Conductive links are discussed herein. A conductive link is an electrically conductive mechanism that form the circuitry that is designed to carry electrical current. As used herein, the term “conductive trace” is an example of a conductive link. Typically, conductive traces are deposited onto the substrate of a circuit assembly. Other approaches may be used to produce conductive links of a circuit other than depositing conductive traces. For example, material may be etched or ablated to reveal conductive material. Conductive material (e.g., indium tin oxide (ITO)) may coat surfaces.

Typically, conductive traces are formed from fired high solids systems or PTF polymer thick film systems that allow circuits to be drawn or printed on a variety of substrate materials. The inks from which these traces are formed usually contain conductive materials such as powdered or flaked silver or carbon-like materials. In addition, ink with translucent or transparent nano-fibers may be used.

The conductive material used for the conductive links may also be used for the interconnects (between the links and the contacts of the dies). In some implementations (such as face-up placement of the dies), it may be useful to have the interconnection material be transparent. Examples of such material includes amorphous transparent conducting oxides (ATCO), transparent conductive oxides (TCO), transparent conductive carbon nanotube (TCCN), and transparent conductive polymers.

Herein, coatings are discussed. The purpose of the coatings include protection and property altering effect (e.g., color adjustment of LEDs). The protective coating are designed to protect circuitry (e.g., printed circuit boards), connections and components against moisture, water immersion, dust, temperature extremes, oils, chemicals, sulfur and/or environmental corrosion. The purpose of the protective coating is to protect the coated material from environmental factors and thus enhance reliability life of the coated circuitry. Typically, the suitable protective coatings are clear, thin, have low viscosity, are chemically resistant, thermally and electrically stable, and have low surface tension.

In at least one implementation, in a liquid state, the coating is sprayed over the circuitry of the circuit assembly and thus effectively packages the dies of the circuitry. In addition or as an alternative to spaying, other application techniques may be employed in other implementations. For example, the coating material may be painted, printed, brushing, deposited, dispensed, powder-coated, coated, sealed, covered, glazed, laminated, enameled, incrusted, plastered, or varnished and the like over the dies. The circuit assembly may be dipped, immersed, slathered, bated, doused, drenched, dunked, or plunged into a coating material.

If the coating material is liquid, then coating material may be dried or cured after application. Examples of suitable protective material includes 3M™ Novec™ electronic grade coatings, adhesives (such as those from Dymax Corporation), epoxies (such as those from Epic Resins), conformal coatings, parylene conformal coatings, acrylic, polyurethane, silicone, fluorinated or non-fluorinated parylene, and amorphous fluoropolymer.

Other coatings may be employed also. For example, a coating can be used to adjust the properties of the circuitry and/or the devices. For example, a LED may be coated with phosphor to adjust the color emitted by the LED. Other color adjusting coatings may be used (such as quantum dots).

In the above description of exemplary implementations, for purposes of explanation, specific numbers, materials configurations, and other details are set forth in order to better explain the present invention, as claimed. However, it will be apparent to one skilled in the art that the claimed invention may be practiced using different details than the exemplary ones described herein. In other instances, well-known features are omitted or simplified to clarify the description of the exemplary implementations.

The inventors intend the described exemplary implementations to be primarily examples. The inventors do not intend these exemplary implementations to limit the scope of the appended claims. Rather, the inventors have contemplated that the claimed invention might also be embodied and implemented in other ways, in conjunction with other present or future technologies.

Moreover, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts and techniques in a concrete fashion. The term “techniques,” for instance, may refer to one or more devices, apparatuses, systems, methods, articles of manufacture, and/or computer-readable instructions as indicated by the context described herein.

As used in this application, the term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more,” unless specified otherwise or clear from context to be directed to a singular form.

These processes are illustrated as a collection of blocks in a logical flow graph, which represents a sequence of operations that can be implemented in mechanics alone or a combination with hardware, software, and/or firmware. In the context of software/firmware, the blocks represent instructions stored on one or more computer-readable storage media that, when executed by one or more processors, perform the recited operations.

Note that the order in which the processes are described is not intended to be construed as a limitation, and any number of the described process blocks can be combined in any order to implement the processes or an alternate process. Additionally, individual blocks may be deleted from the processes without departing from the spirit and scope of the subject matter described herein.

The term “computer-readable media” includes computer-storage media. For example, computer-storage media may include, but are not limited to, magnetic storage devices (e.g., hard disk, floppy disk, and magnetic strips), optical disks (e.g., compact disk (CD) and digital versatile disk (DVD)), smart cards, flash memory devices (e.g., thumb drive, stick, key drive, and SD cards), and volatile and non-volatile memory (e.g., random access memory (RAM), read-only memory (ROM)).

Unless the context indicates otherwise, the term “logic” used herein includes hardware, software, firmware, circuitry, logic circuitry, integrated circuitry, other electronic components and/or a combination thereof that is suitable to perform the functions described for that logic.

### Other Ways of Describing Implementations

Below is a listing of different ways to describe the implementations introduced here:

### Example A

A method comprising obtaining one or more unpackaged semiconductor devices on a carrier substratum; directly transferring the one or more unpackaged semiconductor devices from the carrier substratum to a circuit assembly; in-situ packaging the one or more transferred devices by affixing the one or more transferred devices to a circuit substrate of the circuit assembly; interconnecting each semiconductor device of the one or more transferred devices to conductive links of the circuit assembly; applying a coating material to the one or more transferred devices.

The device described in Example A can optionally include unpackaged semiconductor devices which are single discrete devices.

The device described in Example A can optionally include unpackaged semiconductor devices which are selected from a group consisting of light-emitting diodes (LEDs), diodes, transistors, and resistors.

The device described in Example A can optionally include unpackaged semiconductor devices which are light-emitting diodes (LEDs).

The device described in Example A can optionally include unpackaged semiconductor devices which have a diameter of 10-400 microns.

The device described in Example A can optionally include unpackaged semiconductor devices which have a diameter of 90-270 microns.

The device described in Example A can optionally include carrier substratum which is planar material that is flexible and elastomeric, the carrier substratum has an adhesive bonded onto one side.

The device described in Example A can optionally include carrier substratum which is translucent when stretched.

The device described in Example A can optionally include carrier substratum which is interposed between a direct transfer mechanism and the circuit assembly.

The device described in Example A can optionally include transferring which includes a reciprocating single-axis motion for the direct transference of each unpackaged semiconductor device from the carrier substratum to the circuit assembly.

The device described in Example A can optionally include transferring which includes placing the unpackaged semiconductor devices onto the circuitry assembly in a face-up fashion.

The device described in Example A can optionally include circuit substrate of the circuit assembly which is planar and is configured to support the transferred dies thereon.

The device described in Example A can optionally include circuit substrate which is no thicker than 0.2 millimeters.

The device described in Example A can optionally include disposing conductive links on the circuit substrate of the circuit assembly.

The device described in Example A can optionally include disposing which occurs before the direct transferring.

The device described in Example A can optionally include conductive links which are conductive traces.

The device described in Example A can optionally include applying an adhesive to affix the one or more transferred devices to the circuit substrate.

The device described in Example A can optionally include interconnecting which includes applying a continuous conductive material between a conductive link to an electrical contact of a transferred device.

The device described in Example A can optionally include applying which includes a transfer of uncured liquid or gel coating material onto and over circuit assembly via actions selected from a group consisting of spraying, painting, printing, brushing, depositing, dispensing, powder-coating, coating, sealing, covering, glazing, laminating, enameling, incrusting, plastering, varnishing, dipping, immersing, slathering, bathing, dousing, drenching, dunking, and plunging.

The device described in Example A can optionally include the coating material which is a protective coating that protects the circuit assembly from environmental factors.

The device described in Example A can optionally include the coating material which is a property-altering coating that adjusts the properties of the transferred device.

### Example B

A method comprising obtaining one or more unpackaged semiconductor devices on a carrier substratum; and/or directly transferring the one or more unpackaged semiconductor devices from the carrier substratum to a circuit assembly, wherein the circuit assembly includes a circuit substrate configured to support transferred devices and its associated circuitry.

The device described in Example B can optionally include unpackaged semiconductor devices which are selected from a group consisting of single discrete devices and integrated circuits (ICs).

The device described in Example B can optionally include the unpackaged semiconductor devices which are selected from a group consisting of light-emitting diodes (LEDs), diodes, transistors, and resistors.

The device described in Example B can optionally include the unpackaged semiconductor devices which are light-emitting diodes (LEDs).

The device described in Example B can optionally include the unpackaged semiconductor devices which have a diameter of 50-300 microns.

The device described in Example B can optionally include the unpackaged semiconductor devices which have a diameter of 100-250 microns.

The device described in Example B can optionally include the carrier substratum which is planar material that is flexible and elastomeric, the carrier substratum has an adhesive bonded onto one side.

The device described in Example B can optionally include the carrier substratum which is translucent when stretched.

The device described in Example B can optionally include the carrier substratum which is interposed between a direct transfer mechanism and the circuit assembly.

The device described in Example B can optionally include the transferring which includes a reciprocating single-axis motion for the direct transference of each unpackaged semiconductor device from the carrier substratum to the circuit assembly.

The device described in Example B can optionally include transferring which includes placing the unpackaged semiconductor devices onto the circuitry assembly in a face-up fashion.

The device described in Example B can optionally include the circuit substrate of the circuit assembly which is planar and is configured to support the transferred dies thereon.

The device described in Example B can optionally include the circuit substrate which is no thicker than 0.2 millimeters.

The device described in Example B can optionally include conductive links on the circuit substrate of the circuit assembly.

The device described in Example B can optionally include the disposing which occurs before the direct transferring.

The device described in Example B can optionally include the conductive links which are conductive traces.

The device described in Example B can optionally include in-situ packaging the one or more transferred devices by affixing the one or more transferred devices to a circuit substrate of the circuit assembly.

The device described in Example B can optionally include the affixing which includes applying an adhesive to affix the one or more transferred devices to the circuit substrate.

The device described in Example B can optionally include in-situ packaging the one or more transferred devices by interconnecting each semiconductor device of the one or more transferred devices to conductive links of the circuit assembly.

The device described in Example B can optionally include the interconnecting which includes applying a continuous conductive material between a conductive link to an electrical contact of a transferred device.

The device described in Example B can optionally include in-situ packaging the one or more transferred devices by applying a coating material to the one or more transferred devices.

The device described in Example B can optionally include the applying which includes a transfer of uncured liquid or gel coating material onto and over circuit assembly via actions selected from a group consisting of spraying, painting, printing, brushing, depositing, dispensing, powder-coating, coating, sealing, covering, glazing, laminating, enameling, incrusting, plastering, varnishing, dipping, immersing, slathering, bathing, dousing, drenching, dunking, and plunging.

The device described in Example B can optionally include the coating material which is a protective coating that protects the circuit assembly from environmental factors.

The device described in Example B can optionally include the coating material which is a property-altering coating that adjusts the properties of the transferred device.

The device described in Example B can optionally include in-situ packaging the one or more transferred devices by interconnecting each semiconductor device of the one or more transferred devices to conductive links of the circuit assembly; and/or applying a coating material to the one or more transferred devices.

The device described in Example B can optionally include in-situ packaging the one or more transferred devices by interconnecting each semiconductor device of the one or more transferred devices to conductive links of the circuit assembly, the interconnecting including applying a continuous conductive material between a conductive link to an electrical contact of a transferred device; and/or coating the one or more transferred devices with a protective coating that protects the circuit assembly from environmental factors.

### Example C

A method comprising obtaining a circuit assembly, the circuit assembly includes a circuit substrate that has one or more unpackaged semiconductor devices thereon and its associated circuitry; and/or in-situ packaging the devices on the circuit substrate.

The device described in Example C can optionally include in-situ packaging which includes affixing the devices to the circuit substrate of the circuit assembly.

The device described in Example C can optionally include affixing which includes applying an adhesive to affix the one or more transferred devices to the circuit substrate.

The device described in Example C can optionally include in-situ packaging which includes interconnecting each semiconductor device of the one or more transferred devices to conductive links of the circuit assembly.

The device described in Example C can optionally include interconnecting which includes applying a continuous conductive material between a conductive link to an electrical contact of a transferred device.

The device described in Example C can optionally include in-situ packaging which includes applying a coating material to the one or more transferred devices.

The device described in Example C can optionally include applying which includes a transfer of uncured liquid or gel coating material onto and over circuit assembly via actions selected from a group consisting of spraying, painting, printing, brushing, depositing, dispensing, powder-coating, coating, sealing, covering, glazing, laminating, enameling, incrusting, plastering, varnishing, dipping, immersing, slathering, bathing, dousing, drenching, dunking, and plunging.

The device described in Example C can optionally include coating material which is a protective coating that protects the circuit assembly from environmental factors.

The device described in Example C can optionally include coating material which is a property-altering coating that adjusts the properties of the transferred device.

The device described in Example C can optionally include in-situ packaging the one or more transferred devices by interconnecting each semiconductor device of the one or more transferred devices to conductive links of the circuit assembly; and/or applying a applying material to the one or more transferred devices.

The device described in Example C can optionally include in-situ packaging the one or more transferred devices by interconnecting each semiconductor device of the one or more transferred devices to conductive links of the circuit assembly, the interconnecting including applying a continuous conductive material between a conductive link to an electrical contact of a transferred device; and/or applying the one or more transferred devices with a protective applying that protects the circuit assembly from environmental factors.

The device described in Example C can optionally include unpackaged semiconductor devices which are selected from a group consisting of single discrete devices and integrated circuits (ICs).

The device described in Example C can optionally include unpackaged semiconductor devices which are selected from a group consisting of light-emitting diodes (LEDs), diodes, transistors, and resistors.

The device described in Example C can optionally include unpackaged semiconductor devices which are light-emitting diodes (LEDs).

The device described in Example C can optionally include unpackaged semiconductor devices which have a diameter of 50-300 microns.

The device described in Example C can optionally include unpackaged semiconductor devices which have a diameter of 100-250 microns.

The device described in Example C can optionally include circuit substrate of the circuit assembly which is planar and is configured to support the transferred dies thereon.

The device described in Example C can optionally include circuit substrate which is no thicker than 0.2 millimeters.

The device described in Example C can optionally include disposing conductive links on the circuit substrate of the circuit assembly.

### Example D

A method comprising fabricating unpackaged semiconductor devices, wherein the one or more unpackaged semiconductor devices are on a carrier substratum; constructing a circuitry assembly, wherein the constructing includes directly transferring the one or more unpackaged semiconductor devices from the carrier substratum to the circuit assembly, wherein the circuit assembly includes a circuit substrate configured to support transferred devices and its associated circuitry; and/or manufacturing an electronic product, wherein the manufacturing includes incorporating the constructed circuit assembly into operable circuitry of the electronic product.

The device described in Example D can optionally include unpackaged semiconductor devices are selected from a group consisting of single discrete devices and integrated circuits (ICs).

The device described in Example D can optionally include unpackaged semiconductor devices which are selected from a group consisting of light-emitting diodes (LEDs), diodes, transistors, and resistors.

The device described in Example D can optionally include unpackaged semiconductor devices which are light-emitting diodes (LEDs).

The device described in Example D can optionally include unpackaged semiconductor devices which have a diameter of 50-300 microns.

The device described in Example D can optionally include unpackaged semiconductor devices which have a diameter of 100-250 microns.

The device described in Example D can optionally include carrier substratum which is planar material that is flexible and elastomeric, the carrier substratum has an adhesive bonded onto one side.

The device described in Example D can optionally include carrier substratum which is interposed between a direct transfer mechanism and the circuit assembly.

The device described in Example D can optionally include transferring which includes a reciprocating single-axis motion for the direct transference of each unpackaged semiconductor device from the carrier substratum to the circuit assembly.

The device described in Example D can optionally include transferring which includes placing the unpackaged semiconductor devices onto the circuitry assembly in a face-up fashion.

The device described in Example D can optionally include circuit substrate of the circuit assembly which is planar and is configured to support the transferred dies thereon.

The device described in Example D can optionally include circuit substrate which is no thicker than 0.2 millimeters.

The device described in Example D can optionally include disposing conductive links on the circuit substrate of the circuit assembly.

The device described in Example D can optionally include in-situ packaging the one or more transferred devices by affixing the one or more transferred devices to a circuit substrate of the circuit assembly.

The device described in Example D can optionally include affixing which includes applying an adhesive to affix the one or more transferred devices to the circuit substrate.

The device described in Example D can optionally include in-situ packaging the one or more transferred devices by interconnecting each semiconductor device of the one or more transferred devices to conductive links of the circuit assembly.

The device described in Example D can optionally include interconnecting which includes applying a continuous conductive material between a conductive link to an electrical contact of a transferred device.

The device described in Example D can optionally include in-situ packaging the one or more transferred devices by applying a coating material to the one or more transferred devices.

The device described in Example D can optionally include applying which includes a transfer of uncured liquid or gel coating material onto and over circuit assembly via actions selected from a group consisting of spraying, painting, printing, brushing, depositing, dispensing, powder-coating, coating, sealing, covering, glazing, laminating, enameling, incrusting, plastering, varnishing, dipping, immersing, slathering, bathing, dousing, drenching, dunking, and plunging.

The device described in Example D can optionally include coating material which is a protective coating that protects the circuit assembly from environmental factors.

The device described in Example D can optionally include coating material which is a property-altering coating that adjusts the properties of the transferred device.

The device described in Example D can optionally include in-situ packaging the one or more transferred devices by interconnecting each semiconductor device of the one or more transferred devices to conductive links of the circuit assembly; and/or applying a coating material to the one or more transferred devices.

The device described in Example D can optionally include in-situ packaging the one or more transferred devices by interconnecting each semiconductor device of the one or more transferred devices to conductive links of the circuit assembly, the interconnecting including applying a continuous conductive material between a conductive link to an electrical contact of a transferred device; and/or coating the one or more transferred devices with a protective coating that protects the circuit assembly from environmental factors.

### Example E

An apparatus comprising a carrier-to-circuit transfer mechanism that is configured to obtain one or more unpackaged semiconductor devices on a carrier substratum; directly transfer the one or more unpackaged semiconductor devices from the carrier substratum to a circuit assembly; an in-situ packager that is configured to in-situ package the one or more transferred devices by interconnecting each semiconductor device of the one or more transferred devices to conductive links of the circuit assembly; and/or applying a coating material to the one or more transferred devices.

The device described in Example E can optionally include unpackaged semiconductor devices which are single discrete devices.

The device described in Example E can optionally include unpackaged semiconductor devices which are selected from a group consisting of light-emitting diodes (LEDs), diodes, transistors, and resistors.

The device described in Example E can optionally include unpackaged semiconductor devices which are light-emitting diodes (LEDs).

The device described in Example E can optionally include unpackaged semiconductor devices which have a diameter of 10-300 microns.

The device described in Example E can optionally include unpackaged semiconductor devices which have a diameter of 100-250 microns.

The device described in Example E can optionally include carrier substratum which is planar material that is flexible and elastomeric, the carrier substratum has an adhesive bonded onto one side.

The device described in Example E can optionally include carrier substratum which is translucent when stretched.

The device described in Example E can optionally include carrier substratum which is interposed between the carrier-to-circuit transfer mechanism and the circuit assembly.

The device described in Example E can optionally include carrier-to-circuit transfer mechanism which includes a reciprocating single-axis motion for the direct transference of each unpackaged semiconductor device from the carrier substratum to the circuit assembly.

The device described in Example E can optionally include carrier-to-circuit transfer mechanism which places the unpackaged semiconductor devices onto the circuitry assembly in a face-up fashion.

The device described in Example E can optionally include circuit substrate of the circuit assembly which is planar and is configured to support the transferred dies thereon.

The device described in Example E can optionally include circuit substrate which is no thicker than 0.2 millimeters.

The device described in Example E can optionally include interconnecting of the in-situ packager which includes applying a continuous conductive material between a conductive link to an electrical contact of a transferred device.

The device described in Example E can optionally include coating by the in-situ packager which includes a transfer of uncured liquid or gel coating material onto and over circuit assembly via actions selected from a group consisting of spraying, painting, printing, brushing, depositing, dispensing, powder-coating, coating, sealing, covering, glazing, laminating, enameling, incrusting, plastering, varnishing, dipping, immersing, slathering, bathing, dousing, drenching, dunking, and plunging.

The device described in Example E can optionally include coating material which is a protective coating that protects the circuit assembly from environmental factors.

The device described in Example E can optionally include coating material which is a property-altering coating that adjusts the properties of the transferred device.

What is claimed is:

1. A method comprising:
obtaining one or more unpackaged semiconductor devices on a carrier substratum;
directly transferring the one or more unpackaged semiconductor devices from the carrier substratum to a circuit assembly;
in-situ packaging the one or more transferred devices by:
affixing the one or more transferred devices to a circuit substrate of the circuit assembly;
interconnecting each semiconductor device of the one or more transferred devices to conductive links of the circuit assembly;
applying a coating material to the one or more transferred devices.

2. A method as recited in claim 1, wherein the unpackaged semiconductor devices are single discrete devices.

3. A method as recited in claim 1, wherein the unpackaged semiconductor devices are selected from a group consisting of light-emitting diodes (LEDs), diodes, transistors, resistors, capacitors, and fuses.

4. A method as recited in claim 1, wherein the unpackaged semiconductor devices are light-emitting diodes (LEDs).

5. A method as recited in claim 1, wherein the unpackaged semiconductor devices have a diameter of 10-400 microns.

6. A method as recited in claim 1, wherein the unpackaged semiconductor devices have a diameter of 90-270 microns.

7. A method as recited in claim 1, wherein the carrier substratum is planar material that is flexible and elastomeric, the carrier substratum has an adhesive bonded onto one side.

8. A method as recited in claim 1, wherein the carrier substratum is translucent when stretched.

9. A method as recited in claim 1, wherein the carrier substratum is interposed between a direct transfer mechanism and the circuit assembly.

10. A method as recited in claim 1, wherein the transferring includes a reciprocating single-axis motion for the direct transference of each unpackaged semiconductor device from the carrier substratum to the circuit assembly.

11. A method as recited in claim 1, transferring includes placing the unpackaged semiconductor devices onto the circuit assembly in a face-up fashion.

12. A method as recited in claim 1, wherein the circuit substrate of the circuit assembly is planar and is configured to support the transferred dies thereon.

13. A method as recited in claim 1, wherein the circuit substrate is no thicker than 0.2 millimeters.

14. A method as recited in claim 1 further comprising disposing conductive links on the circuit substrate of the circuit assembly.

15. A method as recited in claim 13, wherein the disposing occurs before the direct transferring.

16. A method as recited in claim 13, wherein the conductive links are conductive traces.

17. A method as recited in claim 1, wherein the affixing includes applying an adhesive to affix the one or more transferred devices to the circuit substrate.

18. A method as recited in claim 1, wherein the interconnecting includes applying a continuous conductive material between a conductive link to an electrical contact of a transferred device.

19. A method as recited in claim 1, wherein the applying includes a transfer of uncured liquid or gel coating material onto and over circuit assembly via actions selected from a group consisting of spraying, painting, printing, brushing, depositing, dispensing, powder-coating, coating, sealing, covering, glazing, laminating, enameling, incrusting, plastering, varnishing, dipping, immersing, slathering, bathing, dousing, drenching, dunking, and plunging.

20. A method as recited in claim 1, wherein the coating material is a protective coating that protects the circuit assembly from environmental factors.

21. A method as recited in claim 1, wherein the coating material is a property-altering coating that adjusts the properties of the transferred device.

22. A method comprising:
obtaining one or more unpackaged semiconductor devices on a carrier substratum;
directly transferring the one or more unpackaged semiconductor devices from the carrier substratum to a circuit assembly, wherein the circuit assembly includes a circuit substrate configured to support transferred devices and its associated circuitry.

23. A method as recited in claim 22, wherein the unpackaged semiconductor devices are selected from a group consisting of single discrete devices and integrated circuits (ICs).

24. A method as recited in claim 22, wherein the unpackaged semiconductor devices are selected from a group consisting of light-emitting diodes (LEDs), diodes, transistors, resistors, capacitors, and fuses.

25. A method as recited in claim 22, wherein the unpackaged semiconductor devices are light-emitting diodes (LEDs).

26. A method as recited in claim 22, wherein the unpackaged semiconductor devices have a diameter of 50-300 microns.

27. A method as recited in claim 22, wherein the unpackaged semiconductor devices have a diameter of 100-250 microns.

28. A method as recited in claim 22, wherein the carrier substratum is planar material that is flexible and elastomeric, the carrier substratum has an adhesive bonded onto one side.

29. A method as recited in claim 22, wherein the carrier substratum is translucent when stretched.

30. A method as recited in claim 22, wherein the carrier substratum is interposed between a direct transfer mechanism and the circuit assembly.

31. A method as recited in claim 22, wherein the transferring includes a reciprocating single-axis motion for the direct transference of each unpackaged semiconductor device from the carrier substratum to the circuit assembly.

32. A method as recited in claim 22, transferring includes placing the unpackaged semiconductor devices onto the circuit assembly in a face-up fashion.

33. A method as recited in claim 22, wherein the circuit substrate of the circuit assembly is planar and is configured to support the transferred dies thereon.

34. A method as recited in claim 22, wherein the circuit substrate is no thicker than 0.2 millimeters.

35. A method as recited in claim 22 further comprising disposing conductive links on the circuit substrate of the circuit assembly.

36. A method as recited in claim 35, wherein the disposing occurs before the direct transferring.

37. A method as recited in claim 35, wherein the conductive links are conductive traces.

38. A method as recited in claim 22 further comprising in-situ packaging the one or more transferred devices by affixing the one or more transferred devices to a circuit substrate of the circuit assembly.

39. A method as recited in claim 38, wherein the affixing includes applying an adhesive to affix the one or more transferred devices to the circuit substrate.

40. A method as recited in claim 22 further comprising in-situ packaging the one or more transferred devices by interconnecting each semiconductor device of the one or more transferred devices to conductive links of the circuit assembly.

41. A method as recited in claim 40, wherein the interconnecting includes applying a continuous conductive material between a conductive link to an electrical contact of a transferred device.

42. A method as recited in claim 22 further comprising in-situ packaging the one or more transferred devices by applying a coating material to the one or more transferred devices.

43. A method as recited in claim 42, wherein the applying includes a transfer of uncured liquid or gel coating material onto and over circuit assembly via actions selected from a group consisting of spraying, painting, printing, brushing, depositing, dispensing, powder-coating, coating, sealing, covering, glazing, laminating, enameling, incrusting, plastering, varnishing, dipping, immersing, slathering, bathing, dousing, drenching, dunking, and plunging.

44. A method as recited in claim 42, wherein the coating material is a protective coating that protects the circuit assembly from environmental factors.

45. A method as recited in claim 42, wherein the coating material is a property-altering coating that adjusts the properties of the transferred device.

46. A method as recited in claim 22 further comprising in-situ packaging the one or more transferred devices by:
interconnecting each semiconductor device of the one or more transferred devices to conductive links of the circuit assembly;
applying a coating material to the one or more transferred devices.

47. A method as recited in claim 22 further comprising in-situ packaging the one or more transferred devices by:
interconnecting each semiconductor device of the one or more transferred devices to conductive links of the circuit assembly, the interconnecting including applying a continuous conductive material between a conductive link to an electrical contact of a transferred device;
coating the one or more transferred devices with a protective coating that protects the circuit assembly from environmental factors.

48. A method comprising:
obtaining a circuit assembly, the circuit assembly includes a circuit substrate that has one or more unpackaged semiconductor devices thereon and its associated circuitry;
in-situ packaging the devices on the circuit substrate.

49. A method as recited in claim 48, wherein the in-situ packaging includes affixing the devices to the circuit substrate of the circuit assembly.

50. A method as recited in claim 49, wherein the affixing includes applying an adhesive to affix the one or more transferred devices to the circuit substrate.

51. A method as recited in claim 48, wherein the in-situ packaging includes interconnecting each semiconductor device of the one or more transferred devices to conductive links of the circuit assembly.

52. A method as recited in claim 51, wherein the interconnecting includes applying a continuous conductive material between a conductive link to an electrical contact of a transferred device.

53. A method as recited in claim 48, wherein the in-situ packaging includes applying a coating material to the one or more transferred devices.

54. A method as recited in claim 53, wherein the applying includes a transfer of uncured liquid or gel coating material onto and over circuit assembly via actions selected from a group consisting of spraying, painting, printing, brushing, depositing, dispensing, powder-coating, coating, sealing, covering, glazing, laminating, enameling, incrusting, plastering, varnishing, dipping, immersing, slathering, bathing, dousing, drenching, dunking, and plunging.

55. A method as recited in claim 53, wherein the coating material is a protective coating that protects the circuit assembly from environmental factors.

56. A method as recited in claim 53, wherein the coating material is a property-altering coating that adjusts the properties of the transferred device.

57. A method as recited in claim 48 further comprising in-situ packaging the one or more transferred devices by:
interconnecting each semiconductor device of the one or more transferred devices to conductive links of the circuit assembly;
applying a coating material to the one or more transferred devices.

58. A method as recited in claim 48 further comprising in-situ packaging the one or more transferred devices by:
interconnecting each semiconductor device of the one or more transferred devices to conductive links of the circuit assembly, the interconnecting including applying a continuous conductive material between a conductive link to an electrical contact of a transferred device;
coating the one or more transferred devices with a protective coating that protects the circuit assembly from environmental factors.

59. A method as recited in claim 48, wherein the unpackaged semiconductor devices are selected from a group consisting of single discrete devices and integrated circuits (ICs).

60. A method as recited in claim 48, wherein the unpackaged semiconductor devices are selected from a group consisting of light-emitting diodes (LEDs), diodes, transistors, resistors, capacitors, and fuses.

61. A method as recited in claim 48, wherein the unpackaged semiconductor devices are light-emitting diodes (LEDs).

62. A method as recited in claim 48, wherein the unpackaged semiconductor devices have a diameter of 50-300 microns.

63. A method as recited in claim 48, wherein the unpackaged semiconductor devices have a diameter of 100-250 microns.

64. A method as recited in claim 48, wherein the circuit substrate of the circuit assembly is planar and is configured to support the transferred dies thereon.

65. A method as recited in claim 48, wherein the circuit substrate is no thicker than 0.2 millimeters.

66. A method as recited in claim 48 further comprising disposing conductive links on the circuit substrate of the circuit assembly.

67. A method comprising:
fabricating unpackaged semiconductor devices, wherein the one or more unpackaged semiconductor devices are on a carrier substratum;
constructing a circuit assembly, wherein the constructing includes directly transferring the one or more unpackaged semiconductor devices from the carrier substratum to the circuit assembly, wherein the circuit assembly includes a circuit substrate configured to support transferred devices and its associated circuitry;
manufacturing an electronic product, wherein the manufacturing includes incorporating the constructed circuit assembly into operable circuitry of the electronic product.

68. A method as recited in claim 67, wherein the unpackaged semiconductor devices are selected from a group consisting of single discrete devices and integrated circuits (ICs).

69. A method as recited in claim 67, wherein the unpackaged semiconductor devices are selected from a group consisting of light-emitting diodes (LEDs), diodes, transistors, resistors, capacitors, and fuses.

70. A method as recited in claim 67, wherein the unpackaged semiconductor devices are light-emitting diodes (LEDs).

71. A method as recited in claim 67, wherein the unpackaged semiconductor devices have a diameter of 50-300 microns.

72. A method as recited in claim 67, wherein the unpackaged semiconductor devices have a diameter of 100-250 microns.

73. A method as recited in claim 67, wherein the carrier substratum is planar material that is flexible and elastomeric, the carrier substratum has an adhesive bonded onto one side.

74. A method as recited in claim 67, wherein the carrier substratum is interposed between a direct transfer mechanism and the circuit assembly.

75. A method as recited in claim 67, wherein the transferring includes a reciprocating single-axis motion for the direct transference of each unpackaged semiconductor device from the carrier substratum to the circuit assembly.

76. A method as recited in claim 67, transferring includes placing the unpackaged semiconductor devices onto the circuit assembly in a face-up fashion.

77. A method as recited in claim 67, wherein the circuit substrate of the circuit assembly is planar and is configured to support the transferred dies thereon.

78. A method as recited in claim 67, wherein the circuit substrate is no thicker than 0.2 millimeters.

79. A method as recited in claim 67 further comprising disposing conductive links on the circuit substrate of the circuit assembly.

80. A method as recited in claim 67 further comprising in-situ packaging the one or more transferred devices by affixing the one or more transferred devices to a circuit substrate of the circuit assembly.

81. A method as recited in claim 80, wherein the affixing includes applying an adhesive to affix the one or more transferred devices to the circuit substrate.

82. A method as recited in claim 67 further comprising in-situ packaging the one or more transferred devices by interconnecting each semiconductor device of the one or more transferred devices to conductive links of the circuit assembly.

83. A method as recited in claim 82, wherein the interconnecting includes applying a continuous conductive material between a conductive link to an electrical contact of a transferred device.

84. A method as recited in claim 67 further comprising in-situ packaging the one or more transferred devices by applying a coating material to the one or more transferred devices.

85. A method as recited in claim 84, wherein the applying includes a transfer of uncured liquid or gel coating material onto and over circuit assembly via actions selected from a group consisting of spraying, painting, printing, brushing, depositing, dispensing, powder-coating, coating, sealing, covering, glazing, laminating, enameling, incrusting, plastering, varnishing, dipping, immersing, slathering, bathing, dousing, drenching, dunking, and plunging.

86. A method as recited in claim 84, wherein the coating material is a protective coating that protects the circuit assembly from environmental factors.

87. A method as recited in claim 84, wherein the coating material is a property-altering coating that adjusts the properties of the transferred device.

88. A method as recited in claim 67 further comprising in-situ packaging the one or more transferred devices by:
interconnecting each semiconductor device of the one or more transferred devices to conductive links of the circuit assembly;
applying a coating material to the one or more transferred devices.

89. A method as recited in claim 67 further comprising in-situ packaging the one or more transferred devices by:
interconnecting each semiconductor device of the one or more transferred devices to conductive links of the circuit assembly, the interconnecting including applying a continuous conductive material between a conductive link to an electrical contact of a transferred device;
coating the one or more transferred devices with a protective coating that protects the circuit assembly from environmental factors.

90. An apparatus comprising:
a carrier-to-circuit transfer mechanism that is configured to:
obtain one or more unpackaged semiconductor devices on a carrier substratum;
directly transfer the one or more unpackaged semiconductor devices from the carrier substratum to a circuit assembly;
an in-situ packager that is configured to in-situ package the one or more transferred devices by:
interconnecting each semiconductor device of the one or more transferred devices to conductive links of the circuit assembly;
applying a coating material to the one or more transferred devices.

91. An apparatus as recited in claim 90, wherein the unpackaged semiconductor devices are single discrete devices.

92. An apparatus as recited in claim 90, wherein the unpackaged semiconductor devices are selected from a group consisting of light-emitting diodes (LEDs), diodes, transistors, resistors, capacitors, and fuses.

93. An apparatus as recited in claim 90, wherein the unpackaged semiconductor devices are light-emitting diodes (LEDs).

94. An apparatus as recited in claim 90, wherein the unpackaged semiconductor devices have a diameter of 10-300 microns.

95. An apparatus as recited in claim 90, wherein the unpackaged semiconductor devices have a diameter of 100-250 microns.

96. An apparatus as recited in claim 90, wherein the carrier substratum is planar material that is flexible and elastomeric, the carrier substratum has an adhesive bonded onto one side.

97. An apparatus as recited in claim 90, wherein the carrier substratum is translucent when stretched.

98. An apparatus as recited in claim 90, wherein the carrier substratum is interposed between the carrier-to-circuit transfer mechanism and the circuit assembly.

99. An apparatus as recited in claim 90, wherein the carrier-to-circuit transfer mechanism includes a reciprocating single-axis motion for the direct transference of each unpackaged semiconductor device from the carrier substratum to the circuit assembly.

100. An apparatus as recited in claim 90, the transfer of the carrier-to-circuit transfer mechanism places the unpackaged semiconductor devices onto the circuit assembly in a face-up fashion.

101. An apparatus as recited in claim 90, wherein the circuit substrate of the circuit assembly is planar and is configured to support the transferred dies thereon.

102. An apparatus as recited in claim 90, wherein the circuit substrate is no thicker than 0.2 millimeters.

103. An apparatus as recited in claim 90, wherein the interconnecting of the in-situ packager includes applying a continuous conductive material between a conductive link to an electrical contact of a transferred device.

104. An apparatus as recited in claim 90, wherein the applying of the in-situ packager includes a transfer of uncured liquid or gel coating material onto and over circuit assembly via actions selected from a group consisting of spraying, painting, printing, brushing, depositing, dispensing, powder-coating, coating, sealing, covering, glazing, laminating, enameling, incrusting, plastering, varnishing, dipping, immersing, slathering, bathing, dousing, drenching, dunking, and plunging.

105. An apparatus as recited in claim 90, wherein the coating material is a protective coating that protects the circuit assembly from environmental factors.

106. An apparatus as recited in claim 90, wherein the coating material is a property-altering coating that adjusts the properties of the transferred device.
